(19) United States
(12) Patent Application Publication
(10) Pub. No.: US 2010/0013535 A1
(43) Pub. Date: Jan. 21, 2010

(54) LATCH CIRCUIT

(76) Inventors: Taek-Sang Song, Gyeonggi-do (KR); Dae-Han Kwon, Gyeonggi-do (KR); Jun-Woo Lee, Gyeonggi-do (KR)

Correspondence Address: IP & T Law Firm PLC, 7700 Little River Turnpike, Suite 207, Fairfax, VA, 22003, US

(21) Appl. No.: 12/344,642

(22) Filed: Dec. 29, 2008

(30) Foreign Application Priority Data
Jul. 17, 2008 (KR) 10-2008-0069696

(51) Int. Cl. H03K 3/00

(52) U.S. Cl. 327/218

(57) ABSTRACT

A latch circuit includes a data input/output unit configured to form a current path through a first node in response to an input data to output an output data, a holding unit configured to form a current path through a second node in response to the output data to store the output data, and a clock input unit coupled to the first and second nodes in parallel in response to a clock.

### CROSS-REFERENCE TO RELATED APPLICATIONS

The present invention claims priority of Korean patent application number 10-2008-0069696, filed on Jul. 17, 2008, which is incorporated by reference in its entirety.

### BACKGROUND OF THE INVENTION

The present invention relates to a latch circuit and a flip-flop including the same, and more particularly, to a latch circuit which can be driven under a low power supply voltage, and a flip-flop including the same.

Since the swing width of a signal swinging with respect to a current mode logic (CML) level is less than that of a signal swinging with respect to a complementary metal-oxide semiconductor (CMOS) level, a CML level signal instead of a CMOS level signal is recently used as a frequency of a system clock increases. Moreover, since the CML level signal swings by a constant current, an output signal swings at a constant amplitude, and the CML level signal has an excellent characteristics on jitters and power supply rejection ratio (PSRR).

FIG. 1 is a detailed circuit diagram of a conventional latch circuit. As shown, the conventional latch circuit includes a data input/output unit 101, a holding unit 111, and a clock input unit 121, and the latch circuit employs a CML level signal.

Since a clock CK is toggled, the operation of the latch circuit will be described below according to temporal order. Upon operation of the latch circuit, a bias transistor 127 supplying a current is turned on by a bias voltage VBN.

When the clock CK has a logic high level, a fifth NMOS transistor 123 receiving the clock CK is turned on. Thus, a current path is formed through a first node E and the data input/output unit 101 operates. When an input data IN of a logic high level is inputted to an input terminal D of the data input/output unit 101, a first NMOS transistor 103 is turned on. Accordingly, since a current flows through a first path \textcircled{1}, an inverted output data OUTB becomes a logic low level at an output node /Q. However, since a current does not flow through a second path \textcircled{2}, an output data OUT becomes a logic high level.

When the input data IN becomes a logic low level and an inverted input data INB of a logic high level is inputted to an input terminal /D of the data input/output unit 101, a second NMOS transistor 105 is turned on. Accordingly, since a current flows through the second path \textcircled{2}, the output data OUT becomes a logic low level. The inverted output data OUTB becomes a logic high level.

When the clock CK has a logic low level, a sixth NMOS transistor 125 is turned on. Thus, a current path is formed through a second node F and the holding unit 111 operates. When the input data IN of a logic high level is inputted, a third NMOS transistor 113 is turned off and a fourth NMOS transistor 115 is turned on because the output data OUT was a logic high level and the inverted output data OUTB was a logic low level. Accordingly, a current flows through a fourth path \textcircled{4} so that the inverted output data OUTB is maintained at a logic low level. However, since a current does not flow through a third path \textcircled{3}, the output data OUT is maintained at a logic high level.

On the other hand, when the output data OUT is a logic low level and the inverted output data OUTB is a logic high level, the third NMOS transistor 133 is turned on and the fourth NMOS transistor 115 is turned off. Accordingly, a current flows through the third path \textcircled{3} so that the output data OUT is maintained at a logic low level. However, since a current does not flow through the fourth path \textcircled{4}, the inverted output data OUTB is maintained at a logic high level.

In this way, during the low duration of the clock CK, the latch circuit stores the input data IN inputted during the high duration of the clock CK.

FIG. 2 is a detailed circuit diagram of a conventional flip-flop.

As shown, the conventional flip-flop includes a first data input/output unit 201, a first holding unit 211, a second data input/output unit 221, a second holding unit 231, and a clock input unit 241, and the flip-flop employs a CML level signal.

Unlike the latch circuit, the flip-flop stores data inputted at a rising edge of a clock until the next rising edge of the clock. That is, in the case of the latch circuit, when a value of data is changed during a high voltage level duration (hereinafter referred as a high duration) of the clock, a value of an output data is also changed. However, in the case of the flip-flop, a value of an output data is not changed even though a value of data is changed during the high duration of the clock.

Upon operation of the flip-flop, a bias transistor 251 supplying a current is turned on by a bias voltage VBN. The operations of the first and second data input/output units 201 and 221 and the first and second holing units 211 and 231 are similar to those of the data input/output unit 101 and holing unit 111 of the latch circuit. However, the first data input/output unit 201 is operated during a high duration of an inverted clock CLKB, i.e., a low voltage level duration (hereinafter referred as a low duration) of the clock CLK by the clock input unit 241, and the first holding unit 211 operates during the high duration of the clock CLK. Accordingly, the first holding unit 211 stores the input data IN, which is inputted to the first data input/output unit 201 at the rising edge of the clock CLK, during the high duration of the clock CLK.

The second data input/output unit 221 operates during the high duration of the clock CLK like the first holding unit 211. Accordingly, the second data input/output unit 221 transfers first output data OUT_1 and OUTB_1 of the first holding unit 211 to second output nodes Q and /Q. Subsequently, the second holding unit 231 stores second output data OUT_2 and OUTB_2 at the rising edges of the inverted clock CLKB.

Through the above-described processes, the flip-flop stores data inputted at the first rising edge of the clock CLK until the next rising edge of the clock CLK.

FIG. 3 is a circuit diagram of a conventional frequency divider. As shown, the conventional frequency divider includes first and second latch circuits 301 and 303, which are the same as the latch circuit of FIG. 1, connected in a ring oscillator type. Two clocks CLK and CLKB having an out-of-phase are inputted to clock input terminals of the first and second latch circuits 301 and 303, being crossed. Since output terminals Q and /Q of the second latch circuit 303, which are crossed, are connected to input terminals D and /D of the first latch circuit 301, output data OUT and OUTB of the first latch circuit 301 and output data of the second latch circuit 303 are a clock having half the frequency of the clock CLK, and the phase difference between the output data OUT and OUTB of the first latch circuit 301 and the output data of the second latch circuit 303 is equal to the half cycle of the clock CLK. The conventional frequency divider may be configured with the flip-flop of FIG. 2 instead of the latch circuit of FIG. 1.

The swing widths of output signals of the latch circuit and the flip-flop using the CML level signal correspond a voltage VR applied across a resistor R (shown in FIGS. 1 and 2), which are less than the swing width of the CMOS level signal. However, as illustrated in FIGS. 1 and 2, the conventional latch circuit and flip-flop include one resistor and three transistors which are connected in series. For example, the latch circuit of FIG. 1 includes a resistor R, the first and fifth transistors 103 and 123 and the bias transistor 127 which are connected in series. Herein, since voltage drop occurs in the each transistor, the swing widths of the output signals of the conventional latch circuit and flip-flop greatly decrease as a power supply voltage VDD decreases.

Under a low power supply voltage VDD, since the voltage between the drain and source of the bias transistor being a current source is reduced due to the voltage drop of the each transistor so that the bias transistor cannot operate at the saturation region, characteristics on PSRR are deteriorated in the conventional latch circuit and flip-flop. Accordingly, the conventional latch and flip-flop have difficulty in normally operating under the low power supply voltage VDD.

### SUMMARY OF THE INVENTION

Some embodiments of the present invention are directed to providing a latch circuit which is capable of decreasing internal voltage drop, thereby operating even under a substantially low power supply voltage, a flip-flop and a frequency divider including the same.

In accordance with an aspect of the present invention, there is provided a latch circuit, which includes a data input/output unit configured to form a current path through a first node in response to an input data to output an output data, a holding unit configured to form a current path through a second node in response to the output data to store the output data, and a clock input unit coupled to the first and second nodes in parallel in response to a clock.

In accordance with another aspect of the present invention, there is provided a flip-flop, which includes a first data input/output unit configured to form a current path through a first node in response to an input data to output a first output data, a first holding unit configured to form a current path through a second node in response to the first output data to store the first output data, a second data input/output unit configured to form a current path through a third node in response to the first output data to output a second output data, a second holding unit configured to form a current path through a fourth node in response to the second output data to store the second output data, and a clock input unit coupled to the first to fourth nodes in parallel to control a formation of each of the current paths in response to a clock.

### BRIEF DESCRIPTION OF THE DRAWINGS

FIG. 1 is a schematic circuit diagram of a conventional latch circuit.

FIG. 2 is a schematic circuit diagram of a conventional flip-flop.

FIG. 3 is a schematic circuit diagram of a conventional frequency divider.

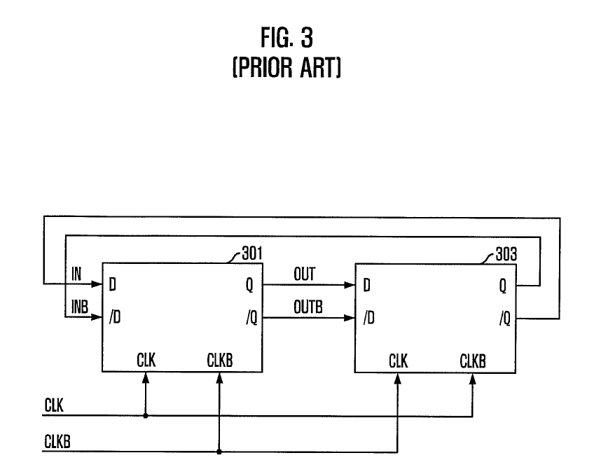

FIG. 4 is a circuit diagram of a latch circuit in accordance with a first embodiment of the present invention.

FIG. 5 is a circuit diagram illustrating an operation of the latch circuit shown in FIG. 4 during a high duration of a clock.

FIG. 6 is a circuit diagram illustrating an operation of the latch circuit shown in FIG. 4 during a low duration of the clock.

FIG. 7 is a circuit diagram of a latch circuit in accordance with a second embodiment of the present invention.

FIG. 8 is a detailed circuit diagram of a flip-flop including the latch circuit in accordance with a third embodiment of the present invention.

FIG. 9 is a graph illustrating a simulation result of a frequency divider including the latch circuit in accordance with the third embodiment of the present invention.

### DESCRIPTION OF SPECIFIC EMBODIMENTS

Other objects and advantages of the present invention can be understood by the following description, and become apparent with reference to the embodiments of the present invention.

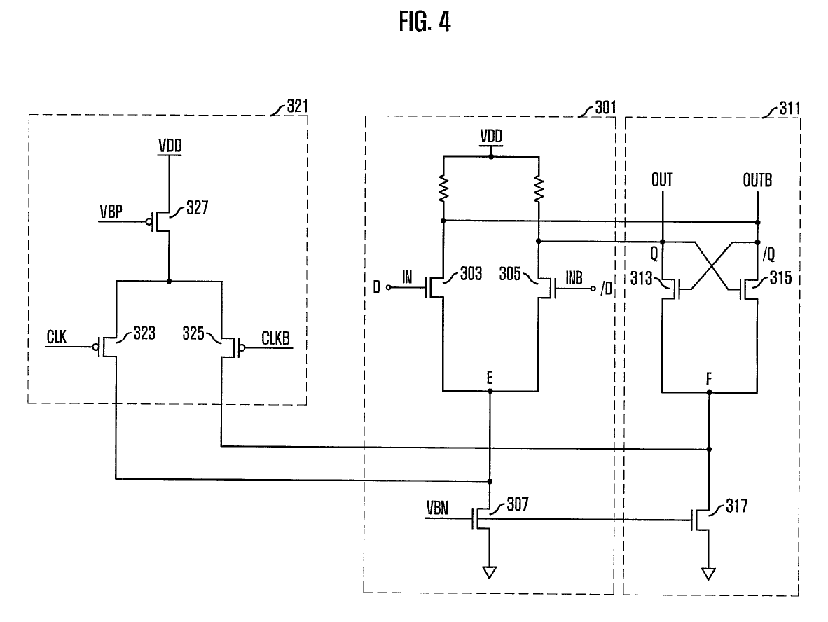

FIG. 4 is a detailed circuit diagram of a latch circuit in accordance with a first embodiment of the present invention.

As shown, the latch circuit in accordance with the first embodiment of the present invention includes a data input/output unit 301, a holding unit 311, and a clock input unit 321.

The data input/output unit 301 forms a current path through a first node E and outputs output data OUT and OUTB, in response to input data IN and INB. The holding unit 311 forms a current path through a second node F and stores the output data OUT and OUTB in response to the output data OUT and OUTB of the data input/output unit 301. The clock input unit 321 is connected to the first and second nodes E and F in parallel to each of the current paths and controls a formation of each of the current paths in response to a clock CLK. For example, the clock input unit 321 may control a load, i.e., impedance, of each current path in response to the clock CLK. As a result, a voltage drop occurring in each of the current paths is substantially reduced by not burdening the current paths with voltage drops through the clock control circuit if the clock control circuit was connected in series to the current paths.

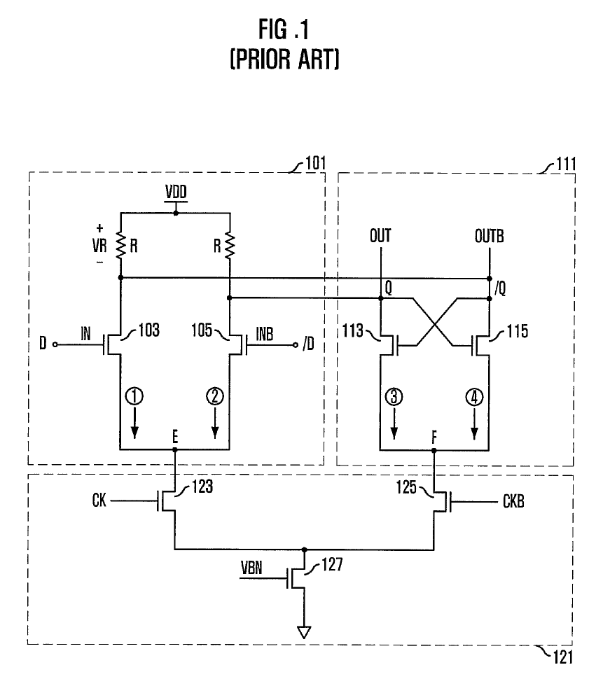

The configurations and operations of the data input/output unit 301 and the holding unit 311 are similar to those of the conventional data input/output unit 101 and holding unit 111. Unlike the conventional technology, the clock input unit 321 is connected to the data input/output unit 301 and the holding unit 311 in parallel. The conventional clock input unit 121 shown in FIG. 1 is connected to the first and second nodes E and F in series, and is turned on/off to control the formation of the current path. However, the clock input unit 321 shown in FIG. 4 is connected to the first and second nodes E and F in parallel, and pulls up or pulls down the first and second nodes E and F to thereby control the formation of the current path. Accordingly, the latch circuit in accordance with the first embodiment of the present invention can prevent voltage drop from occurring in the clock input unit 121 which is connected to the data input/output unit 101 and the holding unit 111 in series in the conventional technology, thereby enabling an operation under a low power supply voltage VDD.

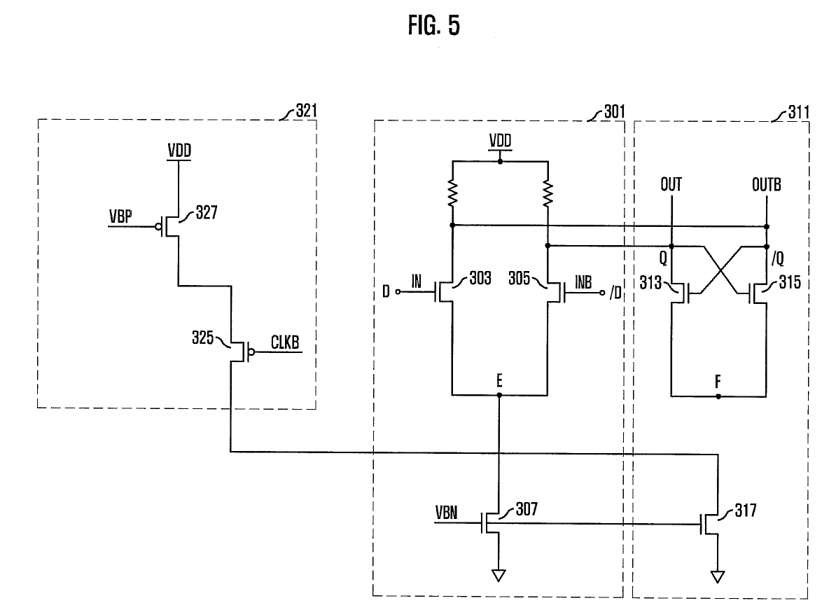

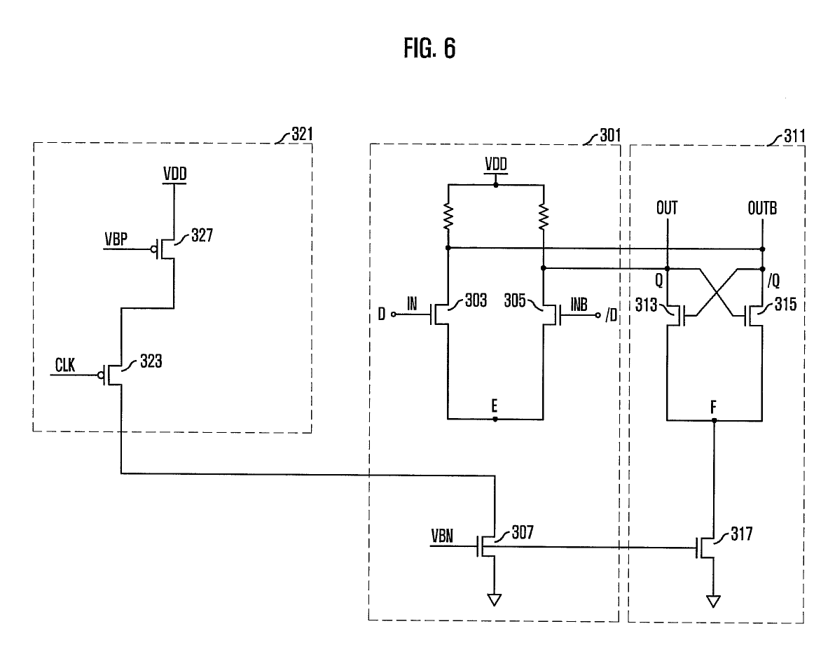

Hereinafter, the following description will be made with reference to FIGS. 5 and 6 as to a detailed operation of the latch circuit in accordance with the first embodiment of the present invention. As described above with reference to FIG. 1, since the clock CLK is to be toggled, the operation of the latch circuit will be described below according to temporal orders. All of the bias transistors 307, 317 and 327 supplying a current are turned-on by bias voltages VBN and VBP.

FIG. 5 is a circuit diagram illustrating an operation of the latch circuit shown in FIG. 4 during a high duration of the clock CLK.

Since an inverted clock CLKB has a logic low level for the high duration of the clock CLK, a sixth PMOS transistor 325 is turned on. The sixth PMOS transistor 325 is connected to the second node F of the holding unit 311, and pulls up the second node F so that third and fourth NMOS transistors 313 and 315 are not turned on. That is, the NMOS transistor is turned on when a voltage difference between its gate terminal and source terminal is equal to or greater than a certain value, for example, 0.7 V. However, voltages of source terminals of the third and fourth NMOS transistors 313 and 315 increase by the pull-up of the second node F, and thus the third and fourth NMOS transistors 313 and 315 are not turned on. At this point, the sixth PMOS transistor 325 may be designed to have a pull-up driving power stronger than a pull-down driving power of the bias transistor 317.

A current path is not formed through the second node F of the holding unit 311 so that the holding unit 311 does not operate. However, since a fifth PMOS transistor 323 does not pull up the first node E of the data input/output unit 301, a current path is formed through the first node E so that the data input/output unit 301 can operate.

The data input/output unit 301 includes the first and second NMOS transistors 303 and 305 and two resistors. The first and second NMOS transistors 303 and 305 are connected to the first node E and pull down output nodes Q and /Q in response to input data IN and INB inputted to respective input terminals D and /D. Two resistors are respectively connected between a power supply voltage VDD terminal and the output nodes Q and /Q to determine the voltage swings of the respective output data OUT and OUTB. As described above with reference to FIG. 1, the first and second NMOS transistors 303 and 305 are turned on/off in response to the respective input data IN and INB, and forms a current path through the first node E to thereby output the input data IN and INB to the respective output nodes Q and /Q.

FIG. 6 is a circuit diagram for describing the operation of the latch circuit shown in FIG. 4 during a low duration of the clock CLK.

For the low duration of the clock CLK, the fifth PMOS transistor 323 is turned on. The fifth PMOS transistor 323 is connected to the first node E of the data input/output unit 301, and pulls up the first node E so that the first and second NMOS transistors 303 and 305 are not turned on. As described above with reference to FIG. 5, the NMOS transistor is turned on when a voltage difference between its gate terminal and source terminal is equal to or greater than a certain value. However, voltages of source terminals of the first and second NMOS transistors 303 and 305 increase by the pull-up of the first node E, and thus the first and second NMOS transistors 303 and 305 are not turned on. At this point, the fifth PMOS transistor 323 may be designed to have a pull-up driving power stronger than a pull-down driving power of the bias transistor 307.

Accordingly, a current path is not formed through the first node E of the data input/output unit 301, and thus the data input/output unit 301 does not operate. However, since the sixth PMOS transistor 325 does not pull up the second node F of the holding unit 311, a current path is formed through the second node F so that the holding unit 311 can operate.

The holding unit 311 includes the third and fourth NMOS transistors 313 and 315 which are connected to the second node F to pull down the output nodes Q and Q/ in response to the output data of the data input/output unit 301, wherein the third and fourth NMOS transistors 313 and 315 have a cross-coupled structure. As described above with reference to FIG. 1, the third and fourth NMOS transistors 313 and 315 are turned on/off in response to a logic level of the output data OUT and OUTB, and forms a current path through the second node F to thereby store the output data OUT and OUTB during the low duration of the clock CLK.

As a result, the latch circuit in accordance with the first embodiment of the present invention performs the function of the conventional latch circuit as it is, and can decrease internal voltage drop by configuring the clock input unit 321 in parallel, thereby operating even under a low power supply voltage VDD.

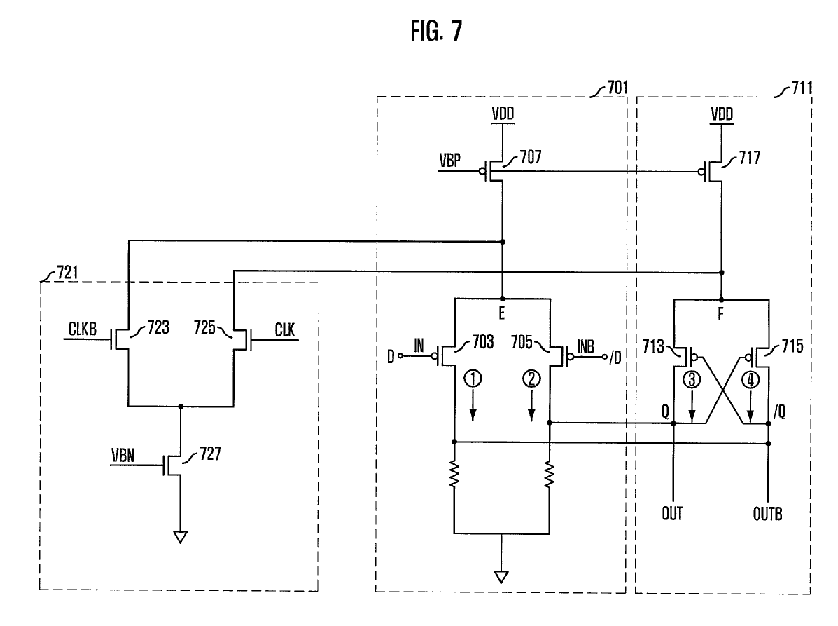

FIG. 7 is a circuit diagram of a latch circuit in accordance with a second embodiment of the present invention.

Referring to FIG. 7, the latch circuit in accordance with the second embodiment of the present invention uses a PMOS transistor instead of an NMOS transistor, and uses an NMOS transistor instead of a PMOS transistor. All of bias transistors 707, 717 and 727 supplying a current are turned-on by bias voltages VBN and VBP. As shown, the latch circuit includes a data input/output unit 701, a holding unit 711, and a clock input unit 721.

The clock input unit 721 includes fifth and sixth NMOS transistors 723 and 725 pulling down a first node E and a second node F in response to a clock CLK and an inverted clock CLKB. The clock input unit 721 is connected to the first and second nodes E and F in parallel and controls a formation of each of the current paths through the nodes E and F in response to the clock CLK and an inverted clock CLKB. For example, the clock input unit 721 may control a load, i.e., impedance, of each of the current paths. As a result, a voltage drop occurring in each of the current paths may be substantially reduced by not burdening the current paths with voltage drops through the clock control circuit if the clock control circuit was connected in series to the current paths. The data input/output unit 701 includes first and second PMOS transistors 703 and 705 which are connected to the first node E to pull up output nodes Q and /Q in response to input data IN and INB, and two resistors which are respectively connected between a ground voltage terminal and the output nodes Q and /Q to determine the voltage swings of output data OUT and OUTB. The holding unit 711 includes third and fourth PMOS transistors 713 and 715 which are connected to the second node F and pull up the output nodes Q and Q/ in response to the output data OUT and OUTB, wherein the third and fourth PMOS transistors 713 and 715 have a cross-coupled structure.

The PMOS transistor is turned on when a voltage difference between its gate and source is equal to or greater than a certain voltage. For a high duration of the clock CLK, since the sixth NMOS transistor 725 is turned on, the second node F is pulled down and voltages of sources of the third and fourth PMOS transistors 713 and 715 are dropped so that the third and fourth PMOS transistors 713 and 715 are not turned on. At this point, the sixth NMOS transistor 725 may be designed to have a pull-down driving power stronger than a pull-up driving power of the bias transistor 717.

A current path is not formed through the second node F of the holding unit 711, and the holding unit 711 does not operate. However, since the fifth NMOS transistor 723 does not pull down the first node E of the data input/output unit 701, a current path is formed through the first node E so that the data input/output unit 701 can operate.

Upon input of the input data IN of a logic low level, the first PMOS transistor 703 is turned on so that a current flows through a first path \textcircled{1}. Accordingly, the output data OUTB becomes a logic high level. Since a current does not flow through a second path \textcircled{2}, the output data OUT is becomes a logic low level.

Upon input of the input data IN of a logic high level, the second PMOS transistor 705 is turned on so that a current flows through the second path \textcircled{2}. Accordingly, the output data OUT becomes a logic high level. Since a current does not flow through the first path \textcircled{1}, the output data OUTB becomes a logic low level.

During a low duration of the clock CLK, since the fifth NMOS transistor 723 is turned on, the first node E is pulled down and voltages of sources of the first and second PMOS transistors 703 and 705 are dropped so that the first and second PMOS transistors 703 and 705 are not turned on. At this point, the fifth NMOS transistor 723 may be designed to have a pull-down driving power stronger than a pull-up driving power of the bias transistor 707.

A current path is not formed through the first node E of the data input/output unit 701, and the data input/output unit 701 does not operate. However, since the sixth NMOS transistor 725 does not pull down the second node F of the holding unit 711, a current path can be formed through the second node F and thus the holding unit 711 can operate.

In a case where the input data IN of a logic low level is inputted, since the output data OUT becomes a logic low level and the output data OUTB is becomes a logic high level, the third PMOS transistor 713 is turned off and the fourth PMOS transistor 715 is turned on. Accordingly, a current flows through a fourth path \textcircled{4}, and the output data OUTB is maintained at a logic high level. However, since a current does not flow through a third path \textcircled{3}, the output data OUT is maintained at a logic low level.

On the other hand, in a case where the output data OUT becomes a logic high level and the output data OUTB becomes a logic low level, the third PMOS transistor 713 is turned on and the fourth PMOS transistor 715 is turned off. Accordingly, a current flows through the third path \textcircled{3}, and the output data OUT is maintained at a logic high level (e.g., a high logic level). However, since a current does not flow the fourth path \textcircled{4}, the output data OUTB is maintained at a logic low level (e.g., a low logic level).

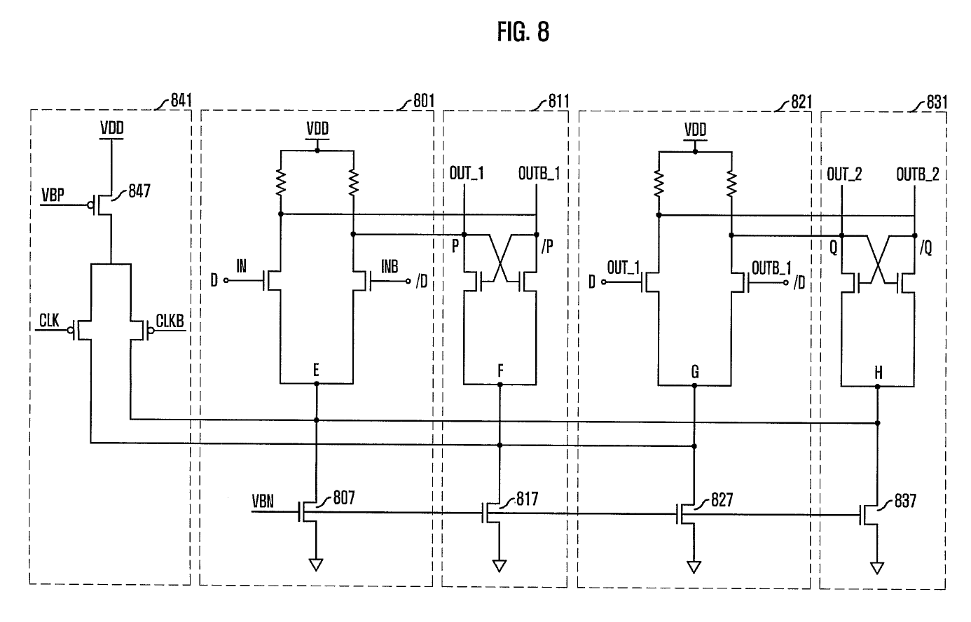

FIG. 8 is a detailed circuit diagram of a flip-flop including the latch circuit in accordance with a third embodiment of the present invention.

Referring to FIG. 8, the flip-flop in accordance with the third embodiment of the present invention includes a first data input/output unit 801, a first holding unit 811, a second data input/output unit 821, a second holding unit 831, and a clock input unit 841.

The first data input/output unit 801 forms a current path trough a first node E and outputs first output data OUT_1 and OUTB_1 in response to input data IN and INB. The first holding unit 811 forms a current path through a second node F and stores the first output data OUT_1 and OUTB_1 in response to the first output data OUT_1 and OUTB_1 of the first data input/output unit 801. The second data input/output unit 821 forms a current path through a third node G and outputs second output data OUT_2 and OUTB_2 in response to the first output data OUT_1 and OUTB_1. The second holding unit 831 forms a current path through a fourth node H and stores the second output data OUT_2 and OUTB_2 in response to the second output data OUT_2 and OUTB_2 of the second data input/output unit 821. The flip-flop including the latch circuit in accordance with the embodiments of the present invention stores the input data IN and INB, which is inputted at a first rising edge of a clock CLK, until a second rising edge of the clock CLK by an operation of each of the elements.

At this point, the clock input unit 841 is connected to the first to fourth nodes E, F, G and H in parallel and controls the formation of the current path in response to the clock CLK. For example, the clock input unit 841 may control a load, i.e., impedance, of each current path. As a result, a voltage drop occurring in each current path is substantially reduced by not burdening the current paths with voltage drops through the clock control circuit if the clock control circuit was connected in series to the current paths.

The configurations and operations of the first and second data input/output units 801 and 821 and the first and second holding units 811 and 831 are similar to those of the conventional first and second data input/output units 201 and 221 and the conventional first and second holding units 211 and 231. Unlike the conventional technology, the clock input unit 841, however, is connected to the first and second data input/output units 801 and 821 and the first and second holding units 811 and 831 in parallel. The conventional clock input unit 241 is connected to the first to fourth nodes E, F, G and H in series, and is turned on/off to control the formation of a current path. However, the clock input unit 841 of the latch circuit in accordance with the third embodiment of the present invention is connected to the first to fourth nodes E, F, G and H in parallel, pulls up or pulls down the first to fourth nodes E, F, G and H to control the formation of a current path. Accordingly, the flip-flop including the latch circuit in accordance with the embodiments of the present invention can prevent voltage drop occurring in the clock input unit 241 which is connected to the first and second data input/output units 201 and 221 and the first and second holding units 211 and 231 in series in the conventional technology, thereby operating even under a low power supply voltage VDD.

Upon operation of the flip-flop, bias transistors 807, 817, 827, 837 and 847 supplying a current are turned-on by bias voltages VBN and VPN. The operations of the first and second data input/output units 801 and 821 and the first and second holding units 811 and 831 are similar to those of the data input/output unit 301 and holding unit 311 of the conventional latch circuit.

However, since the clock input unit 841 pulls up the second and third nodes F and G during a low duration of the clock CLK, the first data input/output unit 801 and the second holding unit 831 and operates for the low duration of the clock CLK. During a high duration of the clock CLK, since the clock input unit 841 pulls up the first and fourth nodes E and H, the first holding unit 811 and the second data input/output unit 821 operate. Accordingly, the first holding unit 811 stores data which the first data input/output unit 801 receives and outputs at the first rising edge of the clock CLK, for the high duration of the clock CLK, and the second data input/output unit 821 receives and outputs the first output data OUT_1 and OUTB_1. For the low duration of the clock CLK, since the clock input unit 841 pulls up the second and third nodes F and G, the second holding unit 831 operates. The second holding unit 831 stores the second output data OUT_2 and OUTB_2.

As a result, the flip-flop in accordance with the third embodiment of the present invention performs the function of the conventional flip-flop as it is, and can decrease internal voltage drop by configuring the clock input unit 841 in parallel, thereby operating even under a low power supply voltage VDD.

Like the latch circuit of FIG. 7, the NMOS transistor of the flip-flop of FIG. 8 can be replaced with a PMOS transistor, and the POMS transistor of the flip-flop of FIG. 8 can be replaced with an NMOS transistor.

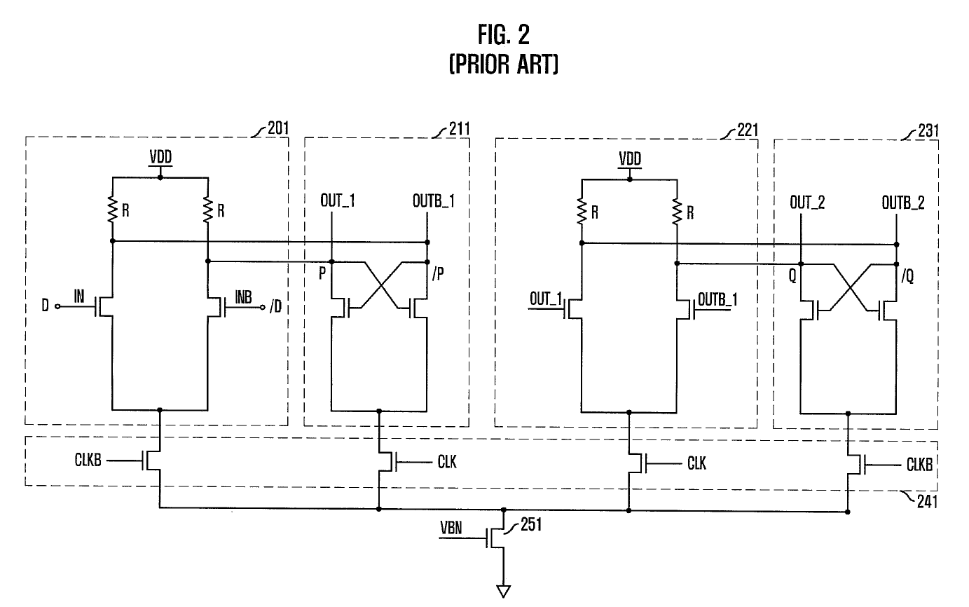

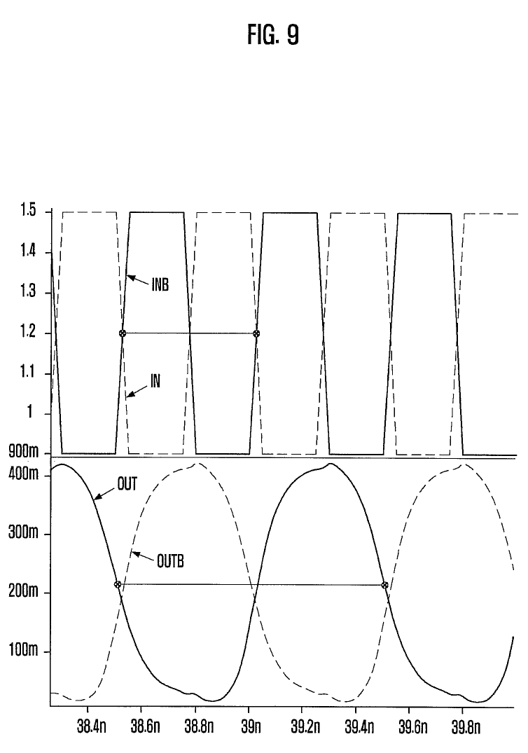

As illustrated in FIG. 2, a frequency divider can be configured with the latch circuit in accordance with the third embodiment of the present invention. FIG. 9 is a graph illustrating a simulation result of the frequency divider including the latch circuit in accordance with the third embodiment of the present invention.

In FIG. 9, the axis of abscissa represents time, and the axis of ordinate represents a voltage level of a signal. It can be seen from FIG. 9 that a frequency of signals IN and INB inputted to the frequency divider is 2 GHz and a period of the signals IN and INB is 500 ps (pico seconds), but a frequency of signals OUT and OUTB divided by the frequency divider is 1 GHz and a period of the signals OUT and OUTB is 1 ns (nano seconds). It can be seen from FIG. 9 that the voltage swings of the signals IN and INB which are inputted to the frequency divider in a CML level scheme is from approximately 900 mV to approximately 1.5V, but the voltage swings of the signals OUT and OUTB divided by the frequency divider is from approximately 0V to approximately 400 mV.

Although the flip-flop including the latch circuit in accordance with the third embodiment of the present invention is applied to the frequency divider, the same simulation result can be obtained.

According to embodiments of the present invention, the latch circuit, the flip-flop and the frequency divider including the same decrease internal voltage drop, thereby operating even under the low power supply voltage.

While the present invention has been described with respect to the specific embodiments, it will be apparent to those skilled in the art that various changes and modifications may be made without departing from the spirit and scope of the invention as defined in the following claims.

What is claimed is:

1. A latch circuit, comprising:
a data input/output unit configured to form a current path through a first node in response to an input data to output an output data;
a holding unit configured to form a current path through a second node in response to the output data to store the output data; and
a clock input unit coupled to the first and second nodes in parallel to each of the current paths and responsive to a clock.

2. The latch circuit of claim 1, wherein the clock input unit controls a formation of each of the current paths in response to the clock.

3. The latch circuit of claim 2, wherein the clock input unit pulls up or pulls down the first node in response to the clock, and pulls up or pulls down the second node in response to an inverted clock.

4. The latch circuit of claim 3, wherein the clock input unit includes a pull-up transistor or a pull-down transistor configured to be turned on/off in response to the clock and the inverted clock.

5. The latch circuit of claim 4, wherein the clock input unit further includes a bias transistor for supplying a current and being turned on in response to a bias voltage.

6. The latch circuit of claim 1, wherein the data input/output unit includes:
a first input unit coupled to the first node to pull up or pull down an output node in response to the input data; and
a resistor coupled between a power supply voltage terminal and the output node to determine a voltage swing width of the output data.

7. The latch circuit of claim 6, wherein the first input unit includes a pull-up transistor or a pull-down transistor configured to be turned on/off in response to the input data.

8. The latch circuit of claim 7, wherein the data input/output unit further includes a bias transistor for supplying a current and being turned on in response to a bias voltage.

9. The latch circuit of claim 1, wherein the holding unit is coupled to the second node to pull up or pull down an output node in response to the output data.

10. The latch circuit of claim 9, wherein the holding unit includes a pull-up transistor or a pull-down transistor configured to be turned on/off in response to the output data, wherein the pull-up transistor or the pull-down transistor has a cross-coupled structure.

11. The latch circuit of claim 10, wherein the holding unit further includes a bias transistor for supplying a current and being turned on in response to a bias voltage.

12. The latch circuit of claim 1, wherein the clock input unit controls an impedance of each of the current paths in response to the clock.

13. A flip-flop, comprising:
a first data input/output unit configured to form a current path through a first node in response to an input data to output a first output data;
a first holding unit configured to form a current path through a second node in response to the first output data to store the first output data;
a second data input/output unit configured to form a current path through a third node in response to the first output data to output a second output data;
a second holding unit configured to form a current path through a fourth node in response to the second output data to store the second output data; and
a clock input unit coupled to the first to fourth nodes in parallel to each of the current paths to control a formation of each of the current paths in response to a clock.

14. The flip-flop of claim 11, wherein the clock input unit pulls up or pulls down the second and third nodes in response to the clock, and pulls up or pulls down the first and fourth nodes in response to an inverted clock.

15. The flip-flop of claim 11, wherein the first data input/output unit includes:
a first input unit coupled to the first node to pull up or pull down a first output node in response to the input data; and
a first resistor coupled between a power supply voltage terminal and the first output node to determine a voltage swing of the first output data.

16. The flip-flop of claim 13, wherein the first holding unit is coupled to the second node to pull up or pull down the first output node in response to the first output data.

17. The flip-flop of claim 14, wherein the second data input/output unit includes:
a second input unit coupled to the third node to pull up or pull down the second output node in response to the first output data; and
a second resistor coupled between a power supply voltage terminal and the second output node to determine a swing width of the second output data.

18. The flip-flop of claim 15, wherein the second holding unit is coupled to the fourth node to pull up or pull down the second output node in response to the second output data.
